(19) United States
(12) Patent Application Publication
(10) Pub. No.: US 2012/0082178 A1
(43) Pub. Date: Apr. 5, 2012

(54) Vertical cavity surface emitting laser and method for manufacturing the same

(75) Inventor: Takemasa Tamanuki, Hong Kong (CN)

(73) Assignee: SAE Magnetics (H.K.) Ltd., Hong Kong (CN)

(21) Appl. No.: 12/926,761

(22) Filed: Dec. 8, 2010

(30) Foreign Application Priority Data
Sep. 30, 2010 (CN) 201010506998.4

(51) Int. Cl. H01S 5/183; H01L 21/28; H01S 5/22

(52) U.S. Cl. 372/46.012; 438/29; 372/46.013; 257/E21.158

(57) ABSTRACT

A vertical cavity surface emitting laser capable of high-speed modulation and stabilized control of polarization direction of the laser light is provided, including a resonator which is formed by stacking a semiconductor substrate, a lower mirror layer formed on the upper side of the semiconductor substrate, an active layer formed on the upper side of the lower mirror layer, and an upper mirror layer including an oxidized layer formed on the upper side of the active layer, and a portion of which is formed in a mesa shape from a predetermined position to the upper surface in a height direction; an insulation layer covering the side surface of the mesa-shaped portion of the resonator, and the upper surface of the non-mesa-shaped portion of the resonator; and electrodes being wired on the upper surface of the upper mirror layer and on the lower surface of the semiconductor substrate, respectively. Further, a portion of the insulation layer formed on the side surface of the mesa-shaped portion of the resonator is formed to be uniformly thicker than another portion along the height direction of the mesa-shaped portion.

### TECHNICAL FIELD

The present invention relates generally to semiconductor lasers and, in particular, to a vertical cavity surface emitting laser. Further, the present invention relates to a method for manufacturing the vertical cavity surface emitting laser.

### BACKGROUND ART

With the development of electronic devices, progress has been made in the areas of higher frequency of the electronic devices and higher-speed transmission of the signals. Along with this, there is also a growing need for higher frequency and higher-speed transmission of vertical cavity surface emitting lasers (VCSEL) which serve as the signal light sources for various electronic devices. Hence, VCSEL capable of high-speed modulation are currently desired.

However, with respect to the optical waveguides, beam splitters, and diffraction gratings which are components of optical devices with VCSEL incorporated, their light passing characteristic and reflection characteristic depend on polarization direction. Therefore, when VCSEL are utilized to be incorporated in optical devices, it is important to control the polarization direction of the VCSEL. However, because conventional VCSEL have an isotropic structure with respect to polarization, there is a problem that it is difficult to control the polarization direction.

To address this problem, there is a technology disclosed in Patent Document 1 which applies an anisotropic stress to the active layer so as to control the polarization direction of the laser light of the VCSEL. This VCSEL forms a metallic strain affixation portion around the mesa portion for generating a strain in the active layer.

[Patent Document 1] JP 11-330630A

However, because the strain affixation portion included in the VCSEL disclosed in the Patent Document 1 is formed of a large-area metal, and the capacitance with the attachment electrode C=ε·S/d (ε: permittivity; S: electrode area; d: electrode interval), the problem occurs that due to the large area S, the capacitance C subjected thereto becomes high. Consequently, the VCSEL no longer follows the change of current, and thereby is unfit for high-speed modulation.

### SUMMARY

In view of the problem described hereinabove, an exemplary object of the present invention is to provide a vertical cavity surface emitting laser capable of high-speed modulation and stabilized control of polarization direction of the laser light.

In order to achieve this exemplary object, an aspect in accordance with the present invention provides a vertical cavity surface emitting laser outputting a laser light in a direction perpendicular to a surface of a semiconductor substrate. The vertical cavity surface emitting laser adopts such a configuration as including: a resonator which is formed by stacking the semiconductor substrate, a lower mirror layer formed on the upper side of the semiconductor substrate, an active layer formed on the upper side of the lower mirror layer, and an upper mirror layer including an oxidized layer formed on the upper side of the active layer, and a portion of which is formed in a mesa shape from a predetermined position to the upper surface in a height direction; an insulation layer covering the side surface of the mesa-shaped portion of the resonator, and the upper surface of the non-mesa-shaped portion of the resonator; and electrodes being wired on the upper surface of the upper mirror layer and on the lower surface of the semiconductor substrate, respectively, a portion of the insulation layer formed on the side surface of the mesa-shaped portion of the resonator being formed to be uniformly thicker than another portion along the height direction of the mesa-shaped portion.

Further, the vertical cavity surface emitting laser adopts such a configuration as: in the insulation layer formed on the side surface of the mesa-shaped portion of the resonator, the portion located in a particular direction is formed to be thicker than the portions located in other directions of four directions mutually orthogonal one after the other passing through the center of the mesa-shaped portion of the resonator.

Further, the vertical cavity surface emitting laser adopts such a configuration as: the insulation layer formed on the side surface of the mesa-shaped portion of the resonator eccentrically forms an outer circumference and an inner circumference positioned at a predetermined height.

According to the present invention, first, around the mesa-shaped portion of the resonator is formed an insulation layer, a portion of which is formed to be uniformly thicker than another portion along the height direction. Next, in a completed product of the vertical cavity surface emitting laser, because of the effect of a heating process in manufacturing, a differential shrinkage of thermal expansion occurs between the resonator and the insulation layer, thereby creating a state of parasitic mechanical stress therein. Hence, because the insulation layer around the mesa-shaped portion is in a state of varying in thickness with position and including the mechanical stress inherently, anisotropic forces act on the active layer. Thereby, it is possible to stabilize the control of the polarization direction of the emitting laser light. Further, because the insulation layer is utilized as the member for applying the anisotropic forces to the active layer, it is possible to keep the capacitance at a low level, thereby being fit for high-speed modulation as well.

Further, the vertical cavity surface emitting laser adopts such a configuration as: in the insulation layer formed on the side surface of the mesa-shaped portion of the resonator, a portion formed to be thicker than another portion is formed to be thicker than the insulation layer formed on the surface of the non-mesa-shaped portion.

Thereby, it is possible to concentrate the mechanical stress on the resonator including the active layer and the oxidized layer without dispersing the mechanical stress on the semiconductor substrate. Therefore, the anisotropic forces further act on the active layer in a concentrated manner; hence, it is possible to further stabilize the control of the polarization direction of the laser light.

Further, the vertical cavity surface emitting laser adopts such a configuration as: the mesa-shaped portion of the resonator is formed to include at least the active layer. Further, the vertical cavity surface emitting laser also adopts such a configuration as: the mesa-shaped portion of the resonator is formed to include the lower mirror layer and a portion of the semiconductor substrate.

Thereby, the anisotropic forces act in a further concentrated manner on the active layer of the mesa-shaped portion. Especially, by applying the mechanical stress to the lower mirror layer as well, the anisotropic forces further act on the active layer in a concentrated manner; hence, it is possible to further stabilize the control of the polarization direction of the laser light.

Further, the vertical cavity surface emitting laser adopts such a configuration as: the insulation layer is formed by carrying out vapor deposition or sputtering in a state of arranging the lamination surface of the resonator to be nonparallel to a deposition material surface or target surface after forming the mesa-shaped portion of the resonator.

Thereby, it is possible to form the insulation layer of the configuration described hereinabove by only arranging the substrate to be inclined to the target surface and the like in the chamber with a conventional insulation layer formation process as it is. Therefore, it is possible to provide a vertical cavity surface emitting laser capable of stabilizing the control of the polarization direction of the laser light in a simple manner and at a low cost.

Further, another aspect in accordance with the present invention provides a method for manufacturing a vertical cavity surface emitting laser outputting a laser light in a direction perpendicular to a surface of a semiconductor substrate. The method adopts such a configuration as including the steps of: forming a resonator by sequentially stacking on the upper side of the semiconductor substrate a lower mirror layer, a layer to become an active layer, and an upper mirror layer including a layer to become an oxidized layer, removing a surrounding portion thereof to form a mesa-shaped portion from a predetermined position to the upper surface in a height direction, and forming the active layer and the oxidized layer; forming an insulation layer to cover the side surface of the mesa-shaped portion of the resonator and the upper surface of the non-mesa-shaped portion of the resonator; and forming electrodes being wired on the upper surface of the upper mirror layer and the lower surface of the semiconductor substrate, respectively, in the step of forming the insulation layer, a portion of the insulation layer covering the side surface of the mesa-shaped portion of the resonator being formed to be uniformly thicker than another portion along the height direction of the mesa-shaped portion.

Further, still another aspect in accordance with the present invention provides a method for manufacturing a vertical cavity surface emitting laser outputting a laser light in a direction perpendicular to a surface of a semiconductor substrate. The method adopts such a configuration as including the steps of: forming a resonator by sequentially stacking on the upper side of the semiconductor substrate a lower mirror layer, a layer to become an active layer, and an upper mirror layer including a layer to become an oxidized layer, removing a surrounding portion thereof to form a mesa-shaped portion from a predetermined position to the upper surface in a height direction, and forming the active layer and the oxidized layer; forming an insulation layer to cover the side surface of the mesa-shaped portion of the resonator and the upper surface of the non-mesa-shaped portion of the resonator; and forming electrodes being wired on the upper surface of the upper mirror layer and the lower surface of the semiconductor substrate, respectively, in the step of forming the insulation layer, the insulation layer being formed by carrying out vapor deposition or sputtering in a state of arranging the lamination surface of the resonator to be nonparallel to a deposition material surface or target surface after forming the mesa-shaped portion of the resonator.

Being configured in the above manner, the present invention is capable of stabilizing the control of the polarization direction of the emitting laser light and, at the same time, keeping the capacitance at a low level so as to be able to respond to high-speed modulation.

### BRIEF DESCRIPTION OF THE DRAWINGS

FIG. 1 is a top view showing a configuration of a vertical cavity surface emitting laser in accordance with a first exemplary embodiment of the present invention;

FIG. 2 is a sectional side view showing the configuration of the vertical cavity surface emitting laser in accordance with the first exemplary embodiment;

FIG. 3 is another sectional side view showing the configuration of the vertical cavity surface emitting laser in accordance with the first exemplary embodiment;

FIGS. 4A to 4C are diagrams for explaining an effect of the vertical cavity surface emitting laser in accordance with the first exemplary embodiment;

FIG. 5 is a flowchart showing a method for manufacturing the vertical cavity surface emitting laser in accordance with the first exemplary embodiment;

FIG. 6 is a diagram showing a process of manufacturing the vertical cavity surface emitting laser in accordance with the first exemplary embodiment;

FIG. 7 is a diagram showing another process of manufacturing the vertical cavity surface emitting laser in accordance with the first exemplary embodiment;

FIG. 8 is a diagram showing yet another process of manufacturing the vertical cavity surface emitting laser in accordance with the first exemplary embodiment;

FIG. 9 is a diagram showing yet another process of manufacturing the vertical cavity surface emitting laser in accordance with the first exemplary embodiment;

FIG. 10 is a diagram showing yet another process of manufacturing the vertical cavity surface emitting laser in accordance with the first exemplary embodiment;

FIG. 11 is a diagram showing yet another process of manufacturing the vertical cavity surface emitting laser in accordance with the first exemplary embodiment;

FIG. 12 is a diagram showing yet another process of manufacturing the vertical cavity surface emitting laser in accordance with the first exemplary embodiment;

FIG. 13 is a sectional side view showing a configuration of a vertical cavity surface emitting laser in accordance with a second exemplary embodiment of the present invention;

FIG. 14 is another sectional side view showing the configuration of the vertical cavity surface emitting laser in accordance with the second exemplary embodiment;

FIG. 15 is a sectional side view showing a configuration of a modification of the vertical cavity surface emitting laser in accordance with the second exemplary embodiment; and

FIG. 16 is another sectional side view showing the configuration of the modification of the vertical cavity surface emitting laser in accordance with the second exemplary embodiment.

### EXEMPLARY EMBODIMENTS

### A First Exemplary Embodiment

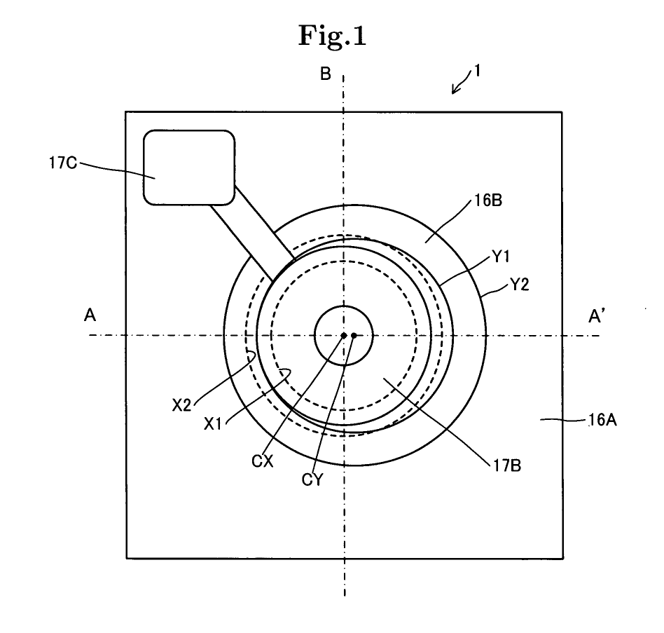

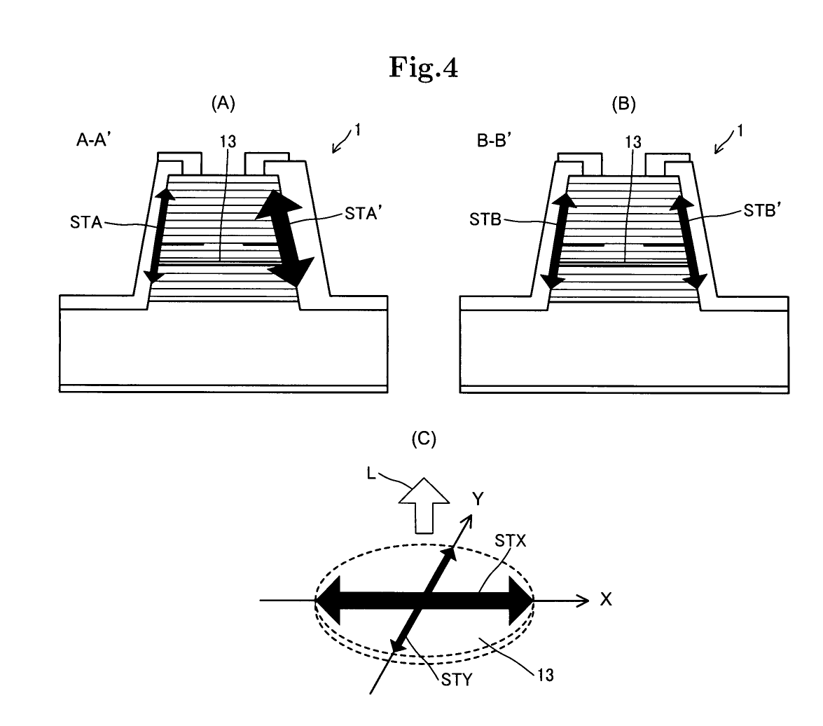

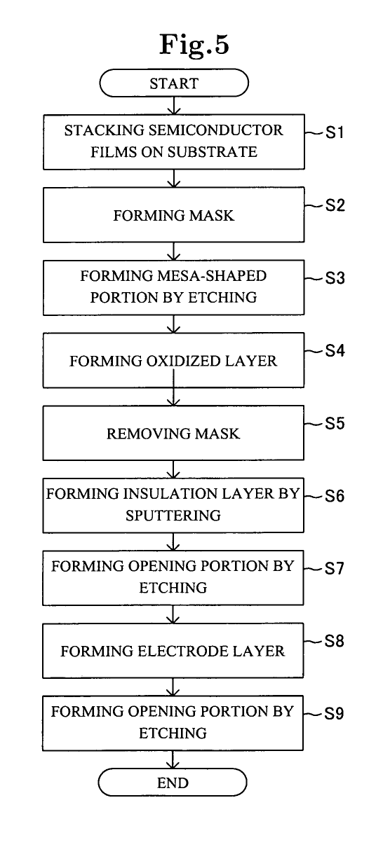

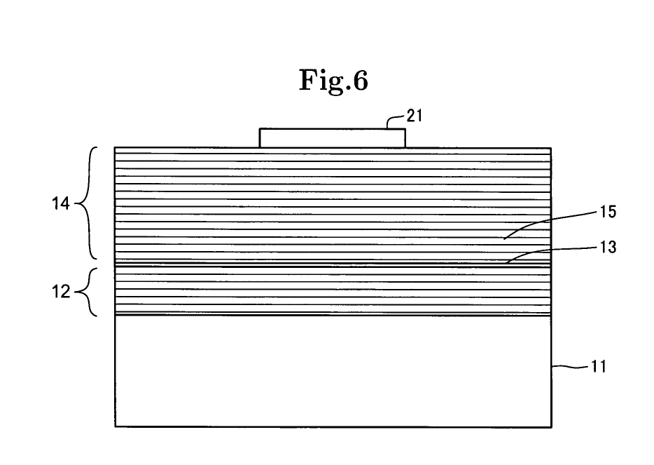

A first exemplary embodiment of the present invention will be described with reference to FIGS. 1 to 12. FIGS. 1 to 3 are diagrams showing a configuration of a vertical cavity surface emitting laser; FIGS. 4A to 4C are diagrams for explaining an effect thereof; FIG. 5 is a flowchart showing a method for manufacturing the vertical cavity surface emitting laser; and FIGS. 6 to 12 are diagrams showing each process of manufacturing the vertical cavity surface emitting laser.

[Configuration]

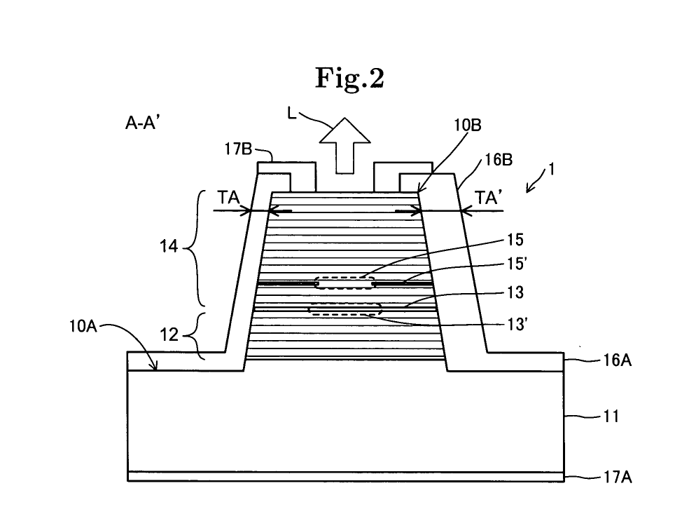

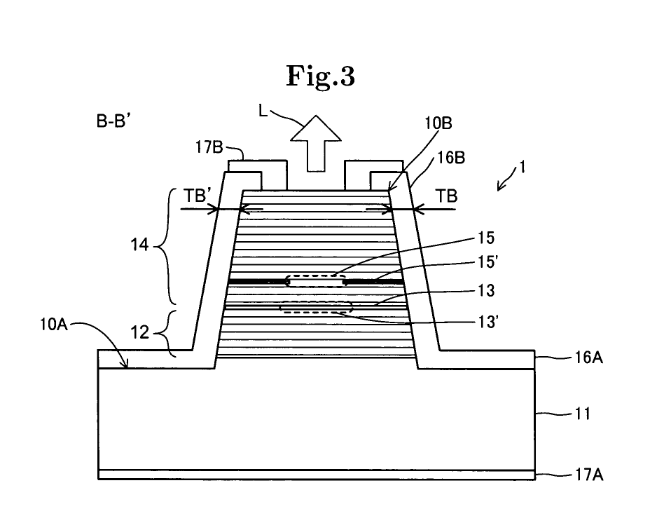

A vertical cavity surface emitting laser 1 in accordance with the first exemplary embodiment outputs a laser light L in a vertical direction to the surface of a semiconductor substrate 11. A configuration thereof will be described with reference to FIGS. 1 to 3. In addition, FIG. 1 is a top view of the vertical cavity surface emitting laser 1; FIG. 2 shows a cross-sectional view of FIG. 1 along the line A-A′; and FIG. 3 shows a cross-sectional view of FIG. 1 along the line B-B′.

As shown in FIGS. 2 and 3, the vertical cavity surface emitting laser 1 includes a resonator which is formed by stacking from below the semiconductor substrate 11, a lower mirror layer 12, and an upper mirror layer 14 including an active layer 13 and an oxidized layer 15′, and a portion of which is formed in a mesa shape (symbol 10B) from a predetermined position to the upper surface in a height direction.

In particular, the semiconductor substrate 11 is, for example, an n-type GaAs (gallium arsenide) substrate. Then, the lower mirror layer 12 formed on the upper side of the semiconductor substrate 11 is, for example, a multilayer film layer composed of Ga (gallium), Al (aluminum), As (arsenic), and the like. In particular, it is an n-type Ga_{0.85}Al_{0.15}As/Ga_{0.1}Al_{0.9}As.

Further, the active layer 13 formed on the upper side of the lower mirror layer 12 is, for example, a GaAs layer. Then, the upper mirror layer 14 formed on the upper side of the active layer 13 is, for example, a multilayer film layer composed of Ga (gallium), Al (aluminum), As (arsenic), and the like. In particular, it is a p-type Ga_{0.85}Al_{0.15}As/Ga_{0.1}Al_{0.9}As. Then, the upper mirror layer 14 has the oxidized layer 15′ therewithin. The oxidized layer 15′ is formed by oxidizing the surrounding portion of an AlAs (aluminum arsenide) layer 15, that is, the surrounding portion of the mesa-shaped portion 10B except the central portion of the mesa-shaped portion 10B.

In particular, to explain with reference to FIGS. 2 and 3, in the inner portion of the annular oxidized layer 15′ formed to locate at a predetermined height in the mesa-shaped portion 10B, an oxidation opening portion (nonoxidation portion: see the dashed-line portion of numeral 15) is formed which is the AlAs layer 15 as it is, and therebelow is positioned an active region 13′ which is the central portion of the active layer 13 in the mesa-shaped portion 10B.

Then, the resonator with a laminate structure is formed in a mesa shape from the position at a predetermined height of the semiconductor substrate 11 to the upper surface (top) of the upper mirror layer 14. In other words, the resonator is composed of a plane portion 10A in a planar shape (non-mesa-shaped portion) which is the lower portion of the semiconductor substrate 11, and the mesa-shaped portion 10B (portion in a mesa shape) which is formed by stacking a portion of the semiconductor substrate 11, the lower mirror layer 12, the active layer 13, and the upper mirror layer 14 to shape up a frustum of circular cone projecting upward from the plane portion 10A. Further, the mesa-shaped portion 10B is not necessarily limited to the shape of a frustum of circular cone, but may also be in other shapes such as a circular cylindrical shape, and a trapezoidal shape in cross section along a height direction and a polygonal shape of the bottom.

Further, on the surface of the resonator of the laminate structure described hereinabove, there are formed insulation layers 16A and 16B of an insulator with respectively predetermined thicknesses. In particular, the plane surface insulation layer 16A is formed to cover the upper surface of the plane portion 10A of the semiconductor substrate 11, and the side surface insulation layer 16B is formed to cover the side surface of the mesa-shaped portion 10B. Further, at the top portion of the mesa-shaped portion 10B, the side surface insulation layer 16B covers only the surrounding portion of the top, and thereby the central portion of the top of the mesa-shaped portion 10B is exposed on the upper side.

Further, on the top of the side surface insulation layer 16B, an upper electrode 17B is formed to be wired on the upper surface of the upper mirror layer 14 exposed at the top. Further, as shown in FIG. 1, the upper electrode 17B is connected with an electrode pad 17C formed on the surface of the plane surface insulation layer 16A through a wiring member formed on the surface of the side surface insulation layer 16B. Further, on the lower surface of the semiconductor substrate 11, a lower electrode 17A is formed to be wired to the semiconductor substrate 11.

Then, by applying a voltage to each of the electrodes 17A and 17B, light is generated in the active layer 13, and intensified through reflecting and reciprocating between the lower mirror layer 12 and the upper mirror layer 14. Then, the generated light passes through the oxidation opening portion 15 surrounded by the oxidized layer 15′, and from the opening portion on the upper side of the upper mirror layer 14, the laser light L is outputted in a direction perpendicular to the semiconductor substrate 11.

Here in the first exemplary embodiment, the side surface insulation layer 16B described hereinbefore has a characteristic that the thickness thereof varies with position. For example, as shown in FIGS. 2 and 3, in four directions mutually orthogonal one after the other passing through the center of the mesa-shaped portion 10B, that is, in directions A, B, A′, and B′ in FIG. 1, the thickness TA′ of the portion located in the particular direction A′ is formed to be uniformly thicker along the height direction than the thicknesses TA, TB, and TB′ of the portions located in the other directions A, B, and B′. In detail, the relationship of thickness between the respective portions is: TA′>TB=TB′>TA; thereby, TA′ is formed to be the thickest. Further, the TA′ portion of the thick side surface insulation layer 16B is formed to be thicker than the plane surface insulation layer 16A which has an approximately uniform thickness.

In other words, the configuration of the side surface insulation layer 16B described hereinabove is such, as shown in FIG. 1, that the inner circumferences X1 and X2 are circular whereas the outer circumferences Y1 and Y2 are elliptic located at respectively predetermined heights of the side surface insulation layer 16B. That is, the center of the inner circumferences CX differs in position from the center of the outer circumferences CY located at each height of the side surface insulation layer 16B, thereby being eccentrically formed each other.

Then, in a completed product of the vertical cavity surface emitting laser configured in the above manner, because of the effect of a heating process in manufacturing, a differential shrinkage of thermal expansion occurs between the resonator (the plane portion 10A and the mesa-shaped portion 10B) and the insulation layers 16A and 16B, thereby creating a state of parasitic mechanical stress therein.

Especially in the first exemplary embodiment, in the side surface insulation layer 16B formed around the mesa-shaped portion 10B to vary in thickness with position, mechanical stress is inherent according to the thickness. That is, as shown in FIGS. 4A and 4B, the stress STA′ inherent in the thickest portion of the side surface insulation layer 16B located in the direction A′ is greater than the stresses STA, STB, and STB′ inherent in other portions. Therefore, because of this stress STA′, a force will act on the active layer 13 in a planar direction. However, as shown in FIG. 4C, a force STX acting in a direction X which is the direction A-A′ will be greater than a force STY acting in a direction Y which is the direction B-B′. As a result, anisotropic forces act on the active layer 13. Thereby, it is possible to stabilize the control of the polarization direction of the emitting laser light. Further, because the insulation layers 16A and 16B are utilized as the member for applying anisotropic forces to the active layer, it is possible to keep the capacitance at a low level, thereby being fit for high-speed modulation as well.

Further, by forming the side surface insulation layer 16B with the thick portion which is also thicker than the plane surface insulation layer 16A on the semiconductor substrate 11, it is possible to concentrate the mechanical stress on the resonator including the active layer 13 and the oxidized layer 15′ without dispersing the mechanical stress on the semiconductor substrate 11. Thereby, the anisotropic forces further act on the active layer 13 in a concentrated manner. Hence, it is possible to further stabilize the control of the polarization direction of the laser light.

Further, in the first exemplary embodiment, because the active layer 13 is formed to be included in the mesa-shaped portion 10B, around the active layer 13 is formed the side surface insulation layer 16B which varies in thickness with position. Hence, the anisotropic forces act on the active layer 13 in a further concentrated manner, thereby making it possible to further stabilize the control of the polarization direction of the laser light.

[Manufacturing Method]

Next, a method for manufacturing the vertical cavity surface emitting laser of the configuration described hereinabove will be described with reference to the flowchart of FIG. 5, and the diagrams of FIGS. 6 to 11 showing the manufacturing aspect of each process.

First, as shown in FIG. 6, on an n-type GaAs substrate which is the semiconductor substrate 11, laminated layers are formed by sequentially stacking the lower mirror layer 12 formed of a multilayer film (n-type Ga_{0.85}Al_{0.15}As/Ga_{0.1}Al_{0.9}As) to become an n-type reflector, the active layer 13 formed of a GaAs layer, and the upper mirror layer 14 formed of a multilayer film (p-type Ga_{0.85}Al_{0.15}As/Ga_{0.1}Al_{0.9}As) to become a p-type reflector (step S1). Further, within the upper mirror layer 14, the AlAs layer 15 is formed to form the oxidized layer 15′ therearound afterward. Further, the forming of the above laminated semiconductor films is, for example, carried out by the MOCVD method (Metal Organic Chemical Vapor Deposition).

Subsequently, as shown in FIG. 6, on the upper surface of the upper mirror layer 14, a dielectric circular mask 21 (25 μm in diameter, for example) is formed to cover part of the upper surface for the forming of the mesa-shaped portion 10B (step S2).

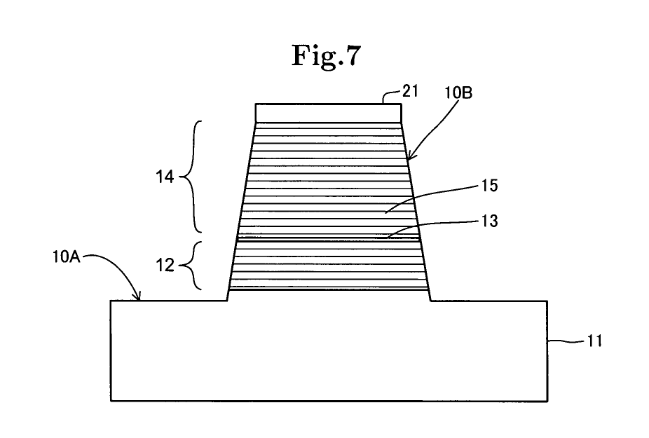

Subsequently, as shown in FIG. 7, through etching down the portion around the circular mask 21 from the upper side, the mesa-shaped portion 10B is formed in the shape of a frustum of circular cone (step S3). At the time, the etching is carried out from the upper side of the upper mirror layer 14 so as to sequentially remove parts of the upper mirror layer 14, the active layer 13, the lower mirror layer 12, and the semiconductor substrate 11. That is, the etching is carried out from above until a portion of the semiconductor substrate 11 is removed by only a predetermined thickness. Thereby, sections of the upper mirror layer 14 (the AlAs layer 15 which will form the oxidized layer 15′ therearound), the active layer 13, and the lower mirror layer 12 are exposed on the lateral side of the mesa-shaped portion 10B. Further, being etched only in part, the semiconductor substrate 11 per se forms the plane portion 10A with the remaining planar portion located below the mesa-shaped portion 10B. Further, the etching is, for example, carried out by the RIE method (Reactive Ion Etching).

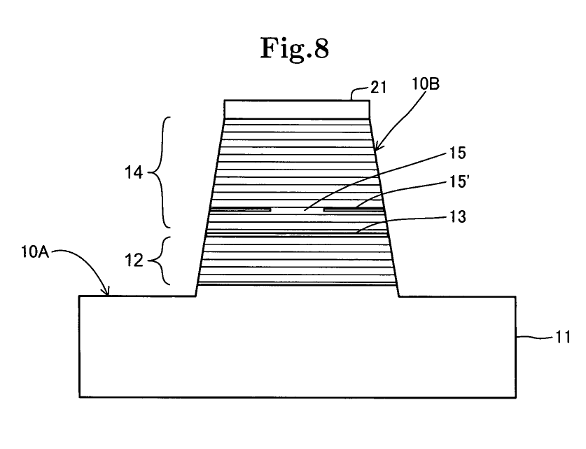

Subsequently, as shown in FIG. 8, the steam oxidation method is utilized to oxidize the AlAs layer 15 which is a component layer of the upper mirror layer 14 which is the reflector on the p side (step S4). At the time, the oxidation of the AlAs layer 15 is carried out sequentially from the lateral side of the mesa-shaped portion 10B toward the center. Therefore, by regulating the time for carrying out the steam oxidation, only the surrounding portion of the mesa-shaped portion 10B becomes the oxidized layer 15′ and, on the contrary, the central portion of the mesa-shaped portion 10B remains as the AlAs layer 15 as it is so as to form the oxidation opening portion (nonoxidation portion). Thereby, it is possible to concentrate the current to flow into the active region 13′ of the active layer 13 located below the oxidation opening portion 15.

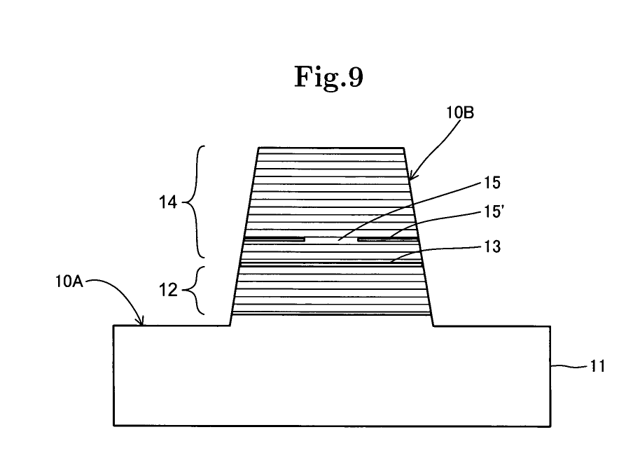

Thereafter, as shown in FIG. 9, the circular mask 21 is removed from the upper surface of the upper mirror layer 14 on which it was formed (step S5).

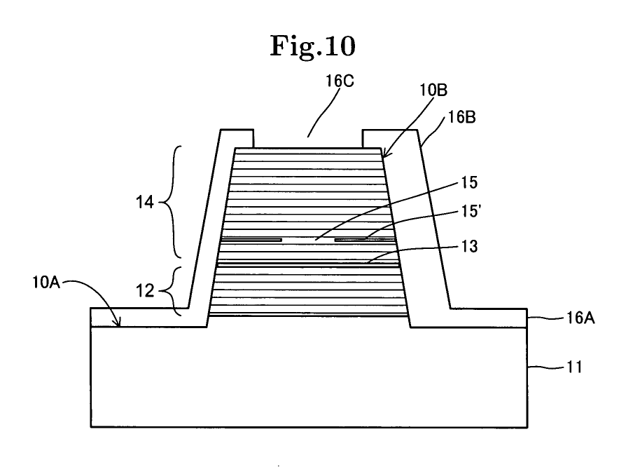

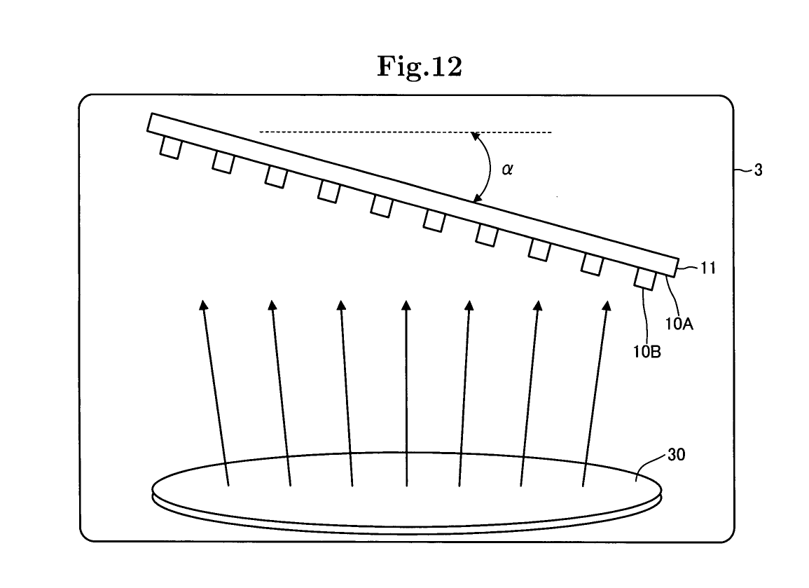

Subsequently, as shown in FIG. 10, the insulation layers 16A and 16B are formed to cover the side surface of the mesa-shaped portion 10B and the surface of the plane portion 10A which were formed as described hereinbefore (step S6). At the time, the forming of the insulation layers 16A and 16B is carried out by depositing dielectric (film-forming) to cover the side surface of the mesa-shaped portion 10B and the upper surface of the plane portion 10A. In particular, as shown in FIG. 12, inside a sputter device 3, the semiconductor substrate 11 on which the mesa-shaped portions 10B are formed is arranged such that the mesa-shaped portions 10B are located on the sputter material (target 30) side. Further, at the time, the surface of the semiconductor substrate 11, that is, the surface of the plane portion 10A, is arranged to be nonparallel to the surface of the target 30. That is, as shown in FIG. 12, the surface of the semiconductor substrate 11 is arranged to be inclined at an angle α ranging from 0° to 90° (30° , for example) to the dashed line parallel to the surface of the target 30.

In the state described hereinabove, as shown with the arrow marks of FIG. 12, the sputter material is scattered from the target 30 to form the insulation layer 16A (plane surface insulation layer) approximately uniform in thickness on the surface of the plane portion 10A, and the insulation layer 16B (side surface insulation layer) varying in thickness with position on the side surface of the mesa-shaped portion 10B. That is, on the side surface of the mesa-shaped portion 10B, the insulation layer 16B is formed to be as thicker in the portion as the side surface faces better to the surface of the target 30. Thereby, the side surface insulation layer 16B formed to cover the side surface of the mesa-shaped portion 10B is, as has been explained with reference to FIGS. 1 to 3, formed such that one portion is uniformly thicker than another portion along the height direction of the mesa-shaped portion 10B.

Herein, the method for forming the insulation layer should not be limited to sputtering as described hereinabove but may also be vapor deposition. In the latter case, the semiconductor substrate 11 on which the mesa-shaped portion 10B is formed is arranged such that the mesa-shaped portion 10B is located on the vapor-deposition material side so as to face the surface of the vapor-deposition material to be heated to sublimate. Further, at the time, the surface of the semiconductor substrate 11, that is, the surface of the plane portion 10A, is arranged to be nonparallel to the surface of the vapor-deposition material. In this manner, it is possible too, in the same manner as described hereinabove, to form the side surface insulation layer 16B to cover the side surface of the mesa-shaped portion 10B such that one portion is uniformly thicker than another portion along the height direction.

Further, by forming the insulation layer described hereinabove, the insulation layer 16B is also formed on the upper surface of the upper mirror layer 14. However, etching is carried out to remove part of the insulation layer 16B (20 μm in diameter, for example) located on the upper side of a central portion of the upper mirror layer 14 (step S7). Thereby, as shown in FIG. 10, an opening portion 16C is formed through which the laser light L is outputted.

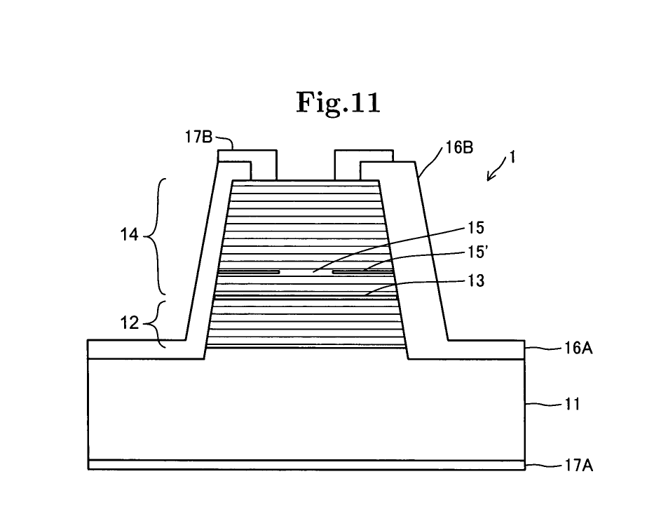

Subsequently, as shown in FIG. 11, vapor deposition is carried out to form an electrode (−) 17A wired on the lower surface of the semiconductor substrate 11, and an electrode (+) 17B wired on the upper surface of the upper mirror layer 14, respectively (step S8). Meanwhile, the electrode (−) 17A and the electrode (+) 17B are made of a bilayer metal formed of a Ti layer (10 nm in thickness) and an Au layer (300 nm in thickness). Thereafter, etching is carried out to remove part of the electrode (+) 17B formed on the upper surface of the upper mirror layer 14, that is, a central portion thereof, so as to expose the upper surface of the upper mirror layer 14 (step S9). Thereby, the opening portion is formed to output the laser light L.

In the above manner, it is possible to manufacture the vertical cavity surface emitting laser which has the configuration described with reference to FIGS. 1 to 3, and is capable of stabilizing the control of the polarization direction of the emitting laser light.

### A Second Exemplary Embodiment

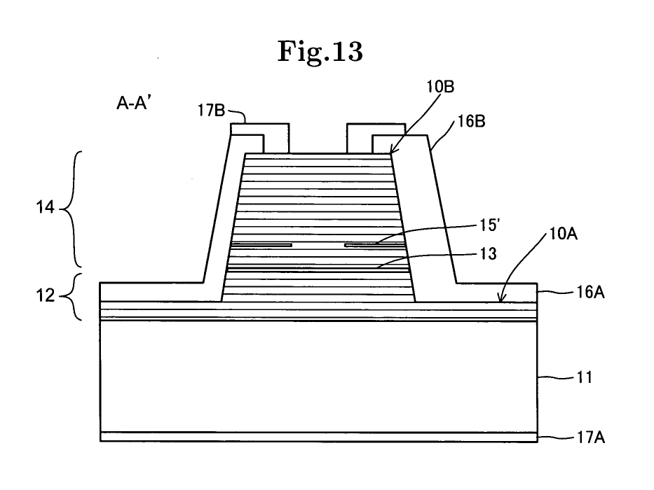

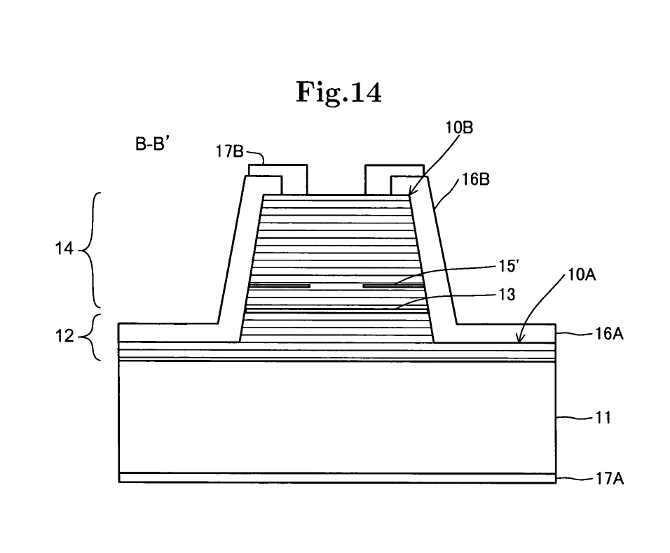

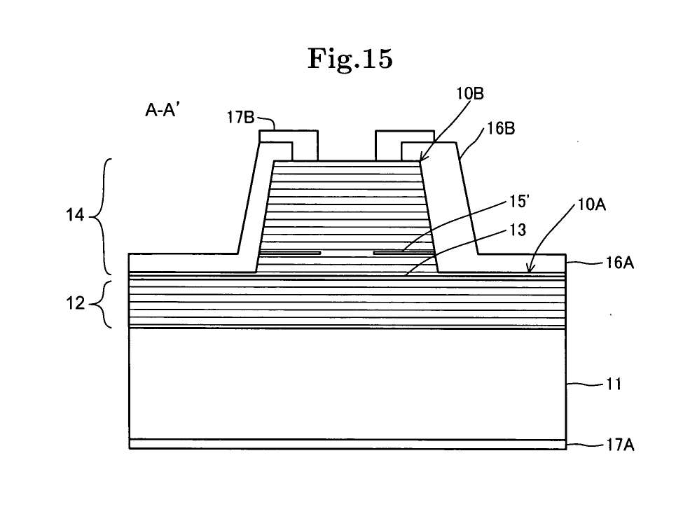

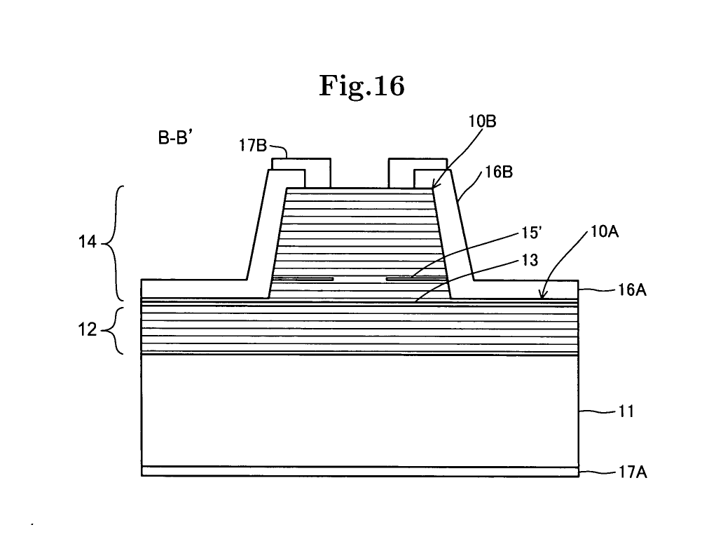

Next, a second exemplary embodiment will be described with reference to FIGS. 13 to 16. FIGS. 13 and 14 are sectional side views showing a configuration of a vertical cavity surface emitting laser in accordance with the second exemplary embodiment. FIGS. 15 and 16 are sectional side views showing a configuration of a modification of the vertical cavity surface emitting laser in accordance with the second exemplary embodiment.

Although the vertical cavity surface emitting laser 1 of the second exemplary embodiment has almost the same configuration as that of the first exemplary embodiment described hereinbefore, the mesa-shaped portion 10B is different in shape from that of the first exemplary embodiment. In particular, although the vertical cavity surface emitting laser 1 in accordance with the second exemplary embodiment has almost the same configuration as shown FIG. 1 if viewed from above, as shown in FIG. 13 which is a cross-sectional view of FIG. 1 along the line A-A′, the mesa-shaped portion 10B is formed from a position halfway in height through the lower mirror layer 12 formed on the upper side of the semiconductor substrate 11 to the upper surface of the upper mirror layer 14. Along with this, the plane portion 10A located under the mesa-shaped portion 10B is formed at a predetermined position in height within the lower mirror layer 12.

Further, it is possible to form the mesa-shaped portion 10B of the above configuration by regulating the time for etching down the portion around the circular mask 21 from the upper side at the time of etching shown in FIG. 7 as explained in the first exemplary embodiment. That is, the etching is carried out from the upper side of the upper mirror layer 14 so as to sequentially remove parts of the upper mirror layer 14, the active layer 13, and the lower mirror layer 12.

In the above manner, being different from that of the first exemplary embodiment, the mesa-shaped portion 10B of the vertical cavity surface emitting laser 1 of the second exemplary embodiment does not include the semiconductor substrate 11. However, because it includes the active layer 13, the side surface insulation layer 16B covering the side surface of the mesa-shaped portion 10B is formed in a state of covering the side surface of the active layer 13. Then, in the same manner as described hereinbefore, the side surface insulation layer 16B varies in thickness with position. For example, FIG. 14 shows another cross-sectional view of FIG. 1 along the line B-B′ in accordance with the second exemplary embodiment. As shown in FIGS. 13 and 14, in four directions mutually orthogonal one after the other passing through the center of the mesa-shaped portion 10B, that is, in directions A, B, A′, and B′ in FIG. 1, the thickness TA′ of the portion located in the particular direction A′ is formed to be uniformly thicker along the height direction than the thicknesses TA, TB, and TB′ of the portions located in the other directions A, B, and B′. In detail, the relationship of thickness between the respective portions is: TA′>TB′=TB′>TA; thereby, TA′ is formed to be the thickest. Further, the TA′ portion of the thick side surface insulation layer 16B is formed to be thicker than the plane surface insulation layer 16A which has an approximately uniform thickness.

Then, in a completed product of the vertical cavity surface emitting laser configured in the above manner, because of the effect of a heating process in manufacturing, a differential shrinkage of thermal expansion occurs between the resonator and the insulation layers 16A and 16B, thereby creating a state of parasitic mechanical stress therein. Especially in the second exemplary embodiment, in the side surface insulation layer 16B formed around the mesa-shaped portion 10B to vary in thickness with position, mechanical stress is inherent according to the thickness. Therefore, in the same manner as described hereinbefore, because the stress inherent in the thickest portion of the side surface insulation layer 16B is greater than the stresses inherent in other portions, a force will act on the active layer 13 in a planar direction. As a result, anisotropic forces act on the active layer 13. Thereby, it is possible to stabilize the control of the polarization direction of the emitting laser light.

However, the mesa-shaped portion 10B of the vertical cavity surface emitting laser 1 is not necessarily limited to including the active layer 13. FIGS. 15 and 16 show a configuration of a modification of the vertical cavity surface emitting laser 1 in accordance with the second exemplary embodiment. As shown in FIG. 15 which is a cross-sectional view of FIG. 1 along the line A-A′, the mesa-shaped portion 10B may also be formed from a position halfway in height through the upper mirror layer 14 formed above the semiconductor substrate 11 to the upper surface of the upper mirror layer 14. Along with this, the plane portion 10A located under the mesa-shaped portion 10B is formed at a predetermined position in height within the upper mirror layer 14. In this case, the mesa-shaped portion 10B is formed to include the AlAs layer 15 therein which will become the oxidized layer 15′ located within the upper mirror layer 14. This is because it is necessary, as described hereinbefore, to form the oxidized layer 15′ from the side surface on which the AlAs layer 15 is exposed.

Further, it is possible to form the mesa-shaped portion 10B of the above configuration by regulating the time for etching down the portion around the circular mask 21 from the upper side at the time of etching shown in FIG. 7 as explained in the first exemplary embodiment. That is, the etching is carried out to remove the portion from the upper side of the upper mirror layer 14 to a position in height below the AlAs layer 15 which will become the oxidized layer 15′ formed halfway through the upper mirror layer 14 but above the active layer 13.

Then, the side surface insulation layer 16B covering the side surface of the mesa-shaped portion 10B of the vertical cavity surface emitting laser 1 in accordance with the modification of the second exemplary embodiment is formed in a state of covering the side surface of the portion located above the active layer 13. Meanwhile, in the same manner as described hereinbefore, the side surface insulation layer 16B varies in thickness with position. For example, FIG. 16 shows another cross-sectional view of FIG. 1 along the line B-B′ in accordance with the modification of the second exemplary embodiment. As shown in FIGS. 15 and 16, in four directions mutually orthogonal one after the other passing through the center of the mesa-shaped portion 10B, that is, in directions A, B, A′, and B′ in FIG. 1, the thickness TA′ of the portion located in the particular direction A′ is formed to be uniformly thicker along the height direction than the thicknesses TA, TB, and TB′ of the portions located in the other directions A, B, and B′. In detail, the relationship of thickness between the respective portions is: TA′>TB =TB′>TA; thereby, TA′ is formed to be the thickest. Further, the TA′ portion of the thick side surface insulation layer 16B is formed to be thicker than the plane surface insulation layer 16A which has an approximately uniform thickness.

Then, in a completed product of the vertical cavity surface emitting laser configured in the above manner, because of the effect of a heating process in manufacturing, a differential shrinkage of thermal expansion occurs between the resonator and the insulation layers 16A and 16B, thereby creating a state of parasitic mechanical stress therein. Especially in the modification, in the side surface insulation layer 16B formed around the mesa-shaped portion 10B to vary in thickness with position, mechanical stress is inherent according to the thickness. Therefore, in the same manner as described hereinbefore, the stress inherent in the thickest portion of the side surface insulation layer 16B is greater than the stresses inherent in other portions. At the time, although in the modification, the side surface insulation layer 16B is not located on the side surface of the active layer 13, because it is located right above the active layer 13, the stresses described hereinabove are also transmitted to the active layer 13. As a result, anisotropic forces act on the active layer 13. Thereby, it is possible to stabilize the control of the polarization direction of the emitting laser light.

1. A vertical cavity surface emitting laser outputting a laser light in a direction perpendicular to a surface of a semiconductor substrate, the vertical cavity surface emitting laser comprising:
a resonator which is formed by stacking the semiconductor substrate, a lower mirror layer formed on the upper side of the semiconductor substrate, an active layer formed on the upper side of the lower mirror layer, and an upper mirror layer including an oxidized layer formed on the upper side of the active layer, and a portion of which is formed in a mesa shape from a predetermined position to the upper surface in a height direction;
an insulation layer covering the side surface of the mesa-shaped portion of the resonator, and the upper surface of the non-mesa-shaped portion of the resonator; and
electrodes being wired on the upper surface of the upper mirror layer and on the lower surface of the semiconductor substrate, respectively,
a portion of the insulation layer formed on the side surface of the mesa-shaped portion of the resonator being formed to be uniformly thicker than another portion along the height direction of the mesa-shaped portion.

2. The vertical cavity surface emitting laser according to claim 1, wherein in the insulation layer formed on the side surface of the mesa-shaped portion of the resonator, the portion located in a particular direction is formed to be thicker than the portions located in other directions of four directions mutually orthogonal one after the other passing through the center of the mesa-shaped portion of the resonator.

3. The vertical cavity surface emitting laser according to claim 1, wherein the insulation layer formed on the side surface of the mesa-shaped portion of the resonator eccentrically forms an outer circumference and an inner circumference positioned at a predetermined height.

4. The vertical cavity surface emitting laser according to claims 1, wherein in the insulation layer formed on the side surface of the mesa-shaped portion of the resonator, a portion formed to be thicker than another portion is formed to be thicker than the insulation layer formed on the surface of the non-mesa-shaped portion.

5. The vertical cavity surface emitting laser according to claims 1, wherein the mesa-shaped portion of the resonator is formed to include at least the active layer.

6. The vertical cavity surface emitting laser according to claim 5, wherein the mesa-shaped portion of the resonator is formed to include the lower mirror layer and a portion of the semiconductor substrate.

7. The vertical cavity surface emitting laser according to claims 1, wherein the insulation layer is formed by carrying out vapor deposition or sputtering in a state of arranging the lamination surface of the resonator to be nonparallel to a deposition material surface or target surface after forming the mesa-shaped portion of the resonator.

8. A method for manufacturing a vertical cavity surface emitting laser outputting a laser light in a direction perpendicular to a surface of a semiconductor substrate, the method comprising the steps of:
forming a resonator by sequentially stacking on the upper side of the semiconductor substrate a lower mirror layer, a layer to become an active layer, and an upper mirror layer including a layer to become an oxidized layer, removing a surrounding portion thereof to form a mesa-shaped portion from a predetermined position to the upper surface in a height direction, and forming the active layer and the oxidized layer;
forming an insulation layer to cover the side surface of the mesa-shaped portion of the resonator and the upper surface of the non-mesa-shaped portion of the resonator; and
forming electrodes being wired on the upper surface of the upper mirror layer and the lower surface of the semiconductor substrate, respectively,
in the step of forming the insulation layer, a portion of the insulation layer covering the side surface of the mesa-shaped portion of the resonator being formed to be uniformly thicker than another portion along the height direction of the mesa-shaped portion.

9. A method for manufacturing a vertical cavity surface emitting laser outputting a laser light in a direction perpendicular to a surface of a semiconductor substrate, the method comprising the steps of:
forming a resonator by sequentially stacking on the upper side of the semiconductor substrate a lower mirror layer, a layer to become an active layer, and an upper mirror layer including a layer to become an oxidized layer, removing a surrounding portion thereof to form a mesa-shaped portion from a predetermined position to the upper surface in a height direction, and forming the active layer and the oxidized layer;
forming an insulation layer to cover the side surface of the mesa-shaped portion of the resonator and the upper surface of the non-mesa-shaped portion of the resonator; and
forming electrodes being wired on the upper surface of the upper mirror layer and the lower surface of the semiconductor substrate, respectively,
in the step of forming the insulation layer, the insulation layer being formed by carrying out vapor deposition or sputtering in a state of arranging the lamination surface of the resonator to be nonparallel to a deposition material surface or target surface after forming the mesa-shaped portion of the resonator.
